(19) United States
(12) Patent Application Publication
(10) Pub. No.: US 2025/0126884 A1
(43) Pub. Date: Apr. 17, 2025

(54) FORKSHEET TRANSISTOR STRUCTURE

(71) Applicant: INTERNATIONAL BUSINESS MACHINES CORPORATION, ARMONK, NY (US)

(72) Inventors: Ruilong Xie, Niskayuna, NY (US); Albert M. Chu, Nashua, NH (US); Tenko Yamashita, Schenectady, NY (US); Brent A. Anderson, Jericho, VT (US)

(21) Appl. No.: 18/487,156

(22) Filed: Oct. 16, 2023

(51) Int. Cl. H01L 27/092; H01L 21/8238; H01L 23/528; H01L 29/06; H01L 29/417; H01L 29/423; H01L 29/66; H01L 29/775; H01L 29/786

(52) U.S. Cl. CPC H10D 84/85; H01L 23/5286; H10D 30/014; H10D 30/43; H10D 30/6729; H10D 30/6735; H10D 30/6757; H10D 62/121; H10D 64/017; H10D 84/0167; H10D 84/0186; H10D 84/0188; H10D 84/038

(57) ABSTRACT

Embodiments of present invention provide a semiconductor structure. The semiconductor structure includes a first and a second dielectric bar each having a left sidewall and a right sidewall; a first set of nanosheets having a first end and a second end that is directly adjacent to the left sidewall of the first dielectric bar; a first conductive layer surrounding the first set of nanosheets and directly adjacent to the left sidewall of the first dielectric bar; a second set of nanosheets having a first end and a second end that is directly adjacent to the left sidewall of the second dielectric bar; and a second conductive layer surrounding the second set of nanosheets; directly adjacent to the left sidewall of the second dielectric bar; and separating the second set of nanosheets from the right sidewall of the first dielectric bar. A method of forming the same is also provided.

### BACKGROUND

The present application relates to manufacturing of semiconductor integrated circuits. More particularly, it relates to a forksheet transistor structure and method of manufacturing the same.

As semiconductor industry moves towards smaller node, field-effect-transistors (FETs) are aggressively scaled to fit into reduced footprint or real estate, which is often dictated by the node size. For example, two nanosheet transistors may be formed directly adjacent a dielectric bar which provides isolation therein-between, which often results in a compact transistor structure.

However, with the dielectric bar directly adjacent to the two nanosheet transistors, that is, directly adjacent to the two set of nanosheets of the two nanosheet transistors with one at a left sidewall and one at a right sidewall of the dielectric bar, it comes with process implication where when the two nanosheet transistors are a same type (e.g., n-type) of transistor and when a pair of different type (e.g., p-type) of transistors (directly adjacent to a neighboring dielectric bar) is formed next to the current pair of transistors, usually no work-function-metal (WFM) undercut suppression may be provided or it is difficult process-wise to provide WFM undercut suppression during a WFM patterning process. On the other hand, when two different types (e.g., one p-type and one n-type) of nanosheet transistors are formed adjacent to the left and right sidewalls of the dielectric bar and when a same type of transistor (from a neighboring dielectric bar) is formed next to a current transistor (of a current dielectric bar) such as, for example, when the two transistors are both p-type transistors, it may require much bigger backside power rails, such as VSS or VDD, to provide power supply to the transistors. This in turn may result in a much tighter spacing between different power rails such as between VSS and VDD in the backside wiring scheme.

### SUMMARY

Embodiments of present invention provide a semiconductor structure. The structure includes a dielectric bar having a left sidewall and a right sidewall; a first set of nanosheets having a first end and a second end, the second end of the first set of nanosheets directly adjacent to the left sidewall of the dielectric bar; a first conductive layer directly adjacent to the left sidewall of the dielectric bar, the conductive layer surrounding the first set of nanosheets and covering the first end of the first set of nanosheets; and a second set of nanosheets and a second conductive layer, the second conductive layer separating the second set of nanosheets from the right sidewall of the dielectric bar. The dielectric bar and the first set of nanosheets thereby forms a forksheet transistor, which is a type of gate-all-around (GAA) transistor with a forked gate structure.

By having the forksheet transistor formed only at one side, such as the left side, of the dielectric bar, there goes away the necessity for WFM undercut suppression when a different type of forksheet transistor is formed next to the other side, such as the right side, of the dielectric bar. Moreover, because the forksheet transistors are more uniformly spaced with each of them being attached to, directly adjacent to, and/or otherwise in contact with one dielectric bar respectively and being consistently at one side thereof, as is described below in more details, backside power rails of reasonable size may be used to provide power supply to the forksheet transistors, which improves the flexibility of wiring scheme and reduces any chance of short between neighboring backside power rails due to tight spacing that otherwise exists in prior art.

In one embodiment, the structure further includes, with the dielectric bar being a first dielectric bar, a second dielectric bar, where the second dielectric bar has a left sidewall parallel to the right sidewall of the first dielectric bar; the second set of nanosheets has a first end and a second end with the second end of the second set of nanosheets being directly adjacent to the left sidewall of the second dielectric bar; and the second conductive layer is directly adjacent to the left sidewall of the second dielectric bar; surrounds the second set of nanosheets; and covers the first end of the second set of nanosheets.

In another embodiment, the structure further includes a first source/drain (S/D) region next to a first side of the first set of nanosheets, and a first backside contact in conductive contact with a bottom surface of the first S/D region.

In yet another embodiment, the structure further includes a second S/D region next to a first side of the second set of nanosheets, and a second backside contact in conductive contact with a bottom surface of the second S/D region.

In yet one more embodiment, the structure further includes a metal connection on top of the first dielectric bar, the metal connection connects the first conductive layer with the second conductive layer.

In one embodiment, the first conductive layer is a gate metal of an n-type transistor, and the second conductive layer is a gate metal of a p-type transistor; the second dielectric bar has a height higher than a height of the first dielectric bar; and the second dielectric bar has a top surface that is coplanar with a top surface of the metal connection.

In another embodiment, the structure further includes a third dielectric bar; a third set of nanosheets; and a third conductive layer, where the third dielectric bar has a left sidewall and a right sidewall with the right sidewall of the third dielectric bar being parallel to the left sidewall of the first dielectric bar and where the first conductive layer separates the first set of nanosheets from the right sidewall of the third dielectric bar; the third set of nanosheets has a second end directly adjacent to the left sidewall of the third dielectric bar; and the third conductive layer is directly adjacent to the left sidewall of the third dielectric bar and surrounds the third set of nanosheets.

In yet another embodiment, the structure further includes a first mid-of-line (MOL) contact in conductive contact with a top surface of the first conductive layer; a third S/D region next to a first side of the third set of nanosheets; and a second MOL contact in conductive contact with a top surface of the third S/D region.

In yet one more embodiment, the structure further includes a first backside power rail (BSPR) in contact with the first backside contact; a second BSPR in contact with the second backside contact; a backside power distribution network (BSPDN) in contact with the first and the second BSPRs; and a back-end-of-line (BEOL) in contact with the first and the second MOL contact.

Embodiments of present invention further provide a method of forming a semiconductor structure. The method includes forming a dielectric bar between a first stack of nanosheets and a second stack of nanosheets, the dielectric bar having a left sidewall directly adjacent to a second portion of the first stack of nanosheets and a right sidewall directly adjacent to a first portion of the second stack of nanosheets; forming a first set of nanosheets by selectively removing a first portion of the first stack of nanosheets that is not directly adjacent to the left sidewall of the dielectric bar; forming a second set of nanosheets by selectively removing the first portion of the second stack of nanosheets directly adjacent to the right sidewall of the dielectric bar; forming a first conductive layer surrounding the first set of nanosheets and directly adjacent to the left sidewall of the dielectric bar; and forming a second conductive layer surrounding the second set of nanosheets and directly adjacent to the right sidewall of the dielectric bar, the second conductive layer separates the second set of nanosheets from the dielectric bar. By having only the first set of nanosheets attached to the left side of the dielectric bar while the second set of nanosheets being separated from the right side of the dielectric bar, it removes the necessity for WFM undercut suppression, thereby significantly simplifying the manufacturing process, when a different type of forksheet transistor is formed next to the right side of the dielectric bar.

In one embodiment, forming the dielectric bar between the first stack of nanosheets and the second stack of nanosheets includes forming a raw stack of nanosheets; creating a trench opening in the raw stack of nanosheets, the trench opening divides the raw stack of nanosheets into the first stack of nanosheets and the second stack of nanosheets; and filling the trench opening with a dielectric material to form the dielectric bar.

In another embodiment, the method further includes, before forming the second set of nanosheets, forming a sidewall spacer next to the right sidewall of the dielectric bar above the first portion of the second stack of nanosheets; covering a second portion of the second stack of nanosheets with a mask layer; selectively removing the sidewall spacer to expose the first portion of the second stack of nanosheets underneath the sidewall spacer.

In one embodiment, forming the second conductive layer includes selectively removing a sacrificial material between the dielectric bar and the second set of nanosheets to create an opening; selectively removing a set of sacrificial sheets between the second set of nanosheets to create spaces; and filling the opening and the spaces with a conductive material in a replacement-metal-gate process to form the second conductive layer.

In another embodiment, the method further includes lowering a height of the dielectric bar to create an opening between the first conductive layer and the second conductive layer and filling the opening with a conductive material to form a metal connection.

In yet another embodiment, the method further includes forming a backside contact by replacing a placeholder underneath a source/drain (S/D) region, the S/D region being adjacent to a first side of the first set of nanosheets.

In yet one more embodiment, the method further includes forming a mid-of-line (MOL) contact in contact with the first conductive layer surrounding the first set of nanosheets.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 18A, 18B, and 18C are demonstrative illustrations of different cross-sectional views of a semiconductor structure in various steps of manufacturing thereof according to embodiments of present invention; and

FIG. 19 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

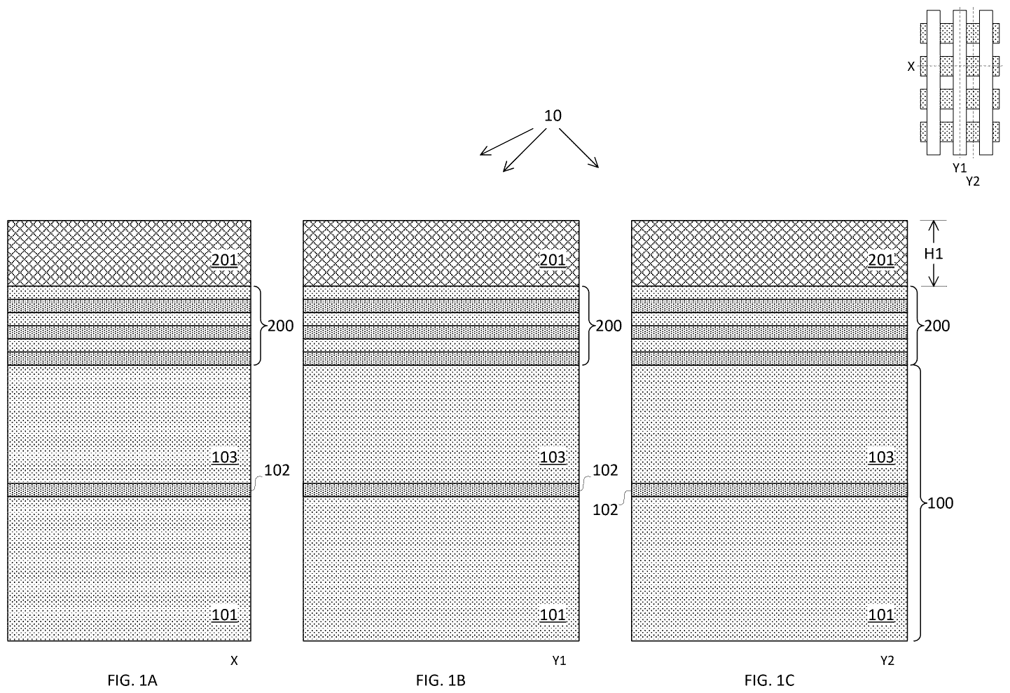

FIGS. 1A, 1B, and 1C are demonstrative illustrations of different cross-sectional views of a semiconductor structure in a step of manufacturing thereof according to one embodiment of present invention. At the upper-right corner of the drawing sheet, a simplified top view of the semiconductor structure is also provided that, for the purpose of illustrating locations of the various cross-sections, may only show (currently present or later formed) of gates, channels, and source/drain regions the semiconductor structure among many other elements.

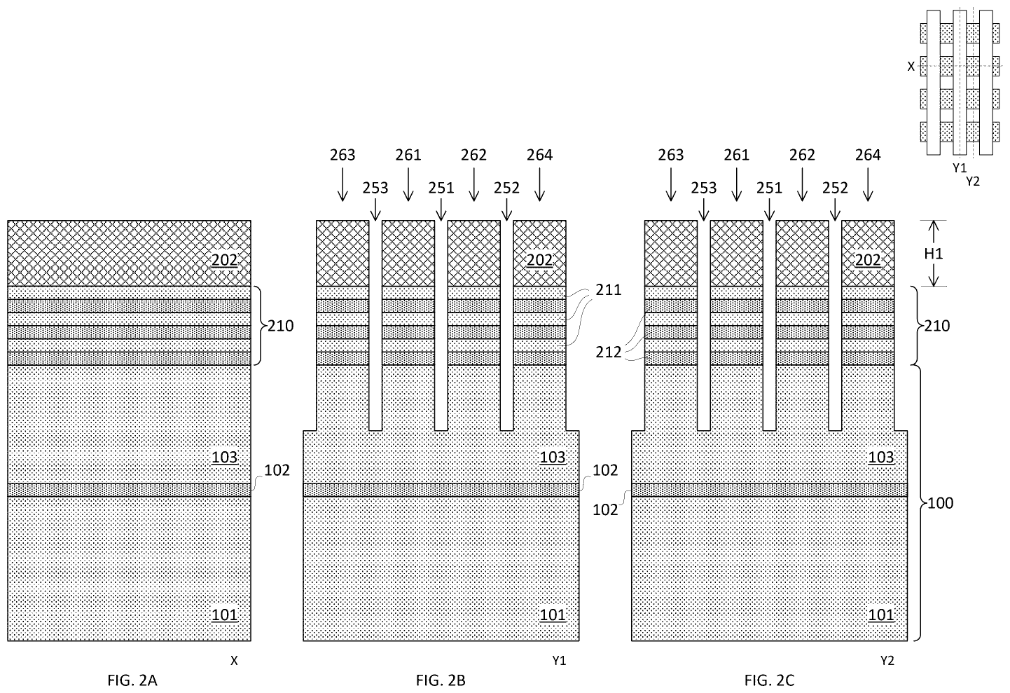

For example, FIG. 1A illustrates a cross-sectional view of the semiconductor structure along a dashed line X. In other words, the cross-sectional view in FIG. 1A is made across the gate in a direction along the length of the gate. FIG. 1B illustrates a cross-sectional view of the semiconductor structure along a dashed line Y1. In other words, the cross-sectional view in FIG. 1B is made across the gate in a direction along the width of the gate. FIG. 1C illustrates a cross-sectional view of the semiconductor structure along a dashed line Y2. In other words, the cross-sectional view in FIG. 1C is made across the S/D region in a direction along the width of the gate. Similarly, FIGS. 2A, 2B, and 2C to FIGS. 18A, 18B, and 18C hereinafter may illustrate cross-sectional views of the semiconductor structure, at various manufacturing stages, in manners corresponding to FIGS. 1A, 1B, and 1C.

Embodiments of present invention provide forming a semiconductor structure 10 by receiving or providing a semiconductor substrate 100. The semiconductor substrate 100 may include a bulk silicon (Si) substrate 101, an etch-stop layer 102 on top of the Si substrate 101, and a Si layer 103 on top of the etch-stop layer 102. In one embodiment, the etch-stop layer 102 may be a silicon-germanium (SiGe) layer to contain a first percentage level of germanium (Ge) such as, for example, 25 at. %, which may be referred to as a SiGe25 layer. Therefore, the etch-stop layer 102 may sometimes be a SiGe25 layer. In another embodiment, the semiconductor substrate 100 may be a silicon-on-insulator (SOI) substrate with an insulating layer such as a silicon-oxide (SiO₂) layer or silicon-nitride (SiN) layer between the Si layer 103 and the bulk substrate 101. The insulating layer may work as an etch-stop layer.

Embodiments of present invention further provide forming a raw stack of nanosheets 200 on top of the Si layer 103 to form one or more nanosheet transistors and forming a hard mask layer 201 on top of the raw stack of nanosheets 200. In one embodiment, as being described below in more details, the raw stack of nanosheets 200 may include a raw stack of blanket Si nanosheets alternating with a raw stack of blanket sacrificial sheets. The hard mask layer 201 may be formed such that it has a height H1 ranging from about 30 nm to about??? 100 nm. The hard mask layer 201 may be formed of SiN, SiBCN, SiCN, SiOCN, SiCO, SiC, AIOx, TiOx, AlNx, or combination of those layers, etc.

FIGS. 2A, 2B, and 2C are demonstrative illustrations of different cross-sectional views of a semiconductor structure in a step of manufacturing thereof according to one embodiment of present invention. More particularly, following the step illustrated in FIGS. 1A, 1B, and 1C, embodiments of present invention provide forming a hard mask 202 from the hard mask layer 201 through a lithographic patterning process such that the hard mask 202 may have shapes of, for example, one or more longitudinal strips that represent shapes of channels of one or more nanosheet transistors to be formed hereinafter. In one embodiment, additional steps may be taken to narrow the openings between the one or more longitudinal strips of the hard mask 202 by forming conformal spacers in the openings through a spacer formation process.

The pattern of the hard mask 202 may be transferred into the raw stack of nanosheets 200 through a selective etching process, thereby transforming the raw stack of nanosheets 200 into one or more stacks of nanosheets 210. For example, the one or more stacks of nanosheets 210 may include a first, a second, a third, and a fourth stack of nanosheets 261, 262, 263, and 264. Each stack of nanosheets 261, 262, 263, and 264 may include a stack of Si nanosheets 211 separated by and/or alternating with a stack of sacrificial sheets 212. In one embodiment, the stack of Si nanosheets 211 may be made of silicon, and the stack of sacrificial sheets 212 may be made of SiGe to include a second percentage level of Ge ranging from 30 at. % to 65 at. %, for example. The sacrificial sheets 212 thus may be referred to as a stack of SiGeXX sheets with XX representing the percentage of Ge such as a stack of SiGe30 sheets or a stack of SiGe65 sheets. The inclusion of Ge in the stack of sacrificial sheets 212 enables a selective etching process during which the stack of sacrificial sheets 212 may be selectively removed in a replacement-metal-gate (RMG) process as being described below in more details.

In transforming the raw stack of nanosheets 200 into the one or more stacks of nanosheets 210, the selective etching process may create one or more trench openings between the one or more stacks of nanosheets 210. For example, a first trench opening 251 may be created between the first and the second stack of nanosheets 261 and 262; a second trench opening 252 may be created between the second and the fourth stack of nanosheets 262 and 264; and a third trench opening 253 may be created between the third and the first stack of nanosheets 263 and 261. The first, the second, and the third trench opening 251, 252, and 253 may start from the hard mask 202, through the raw stack of nanosheets 200, and be made sufficiently deep and partially into the Si layer 103 of the semiconductor substrate 100. The first, the second, and the third trench opening 251, 252, and 253 may be used for forming one or more dielectric bars as being described below in more details.

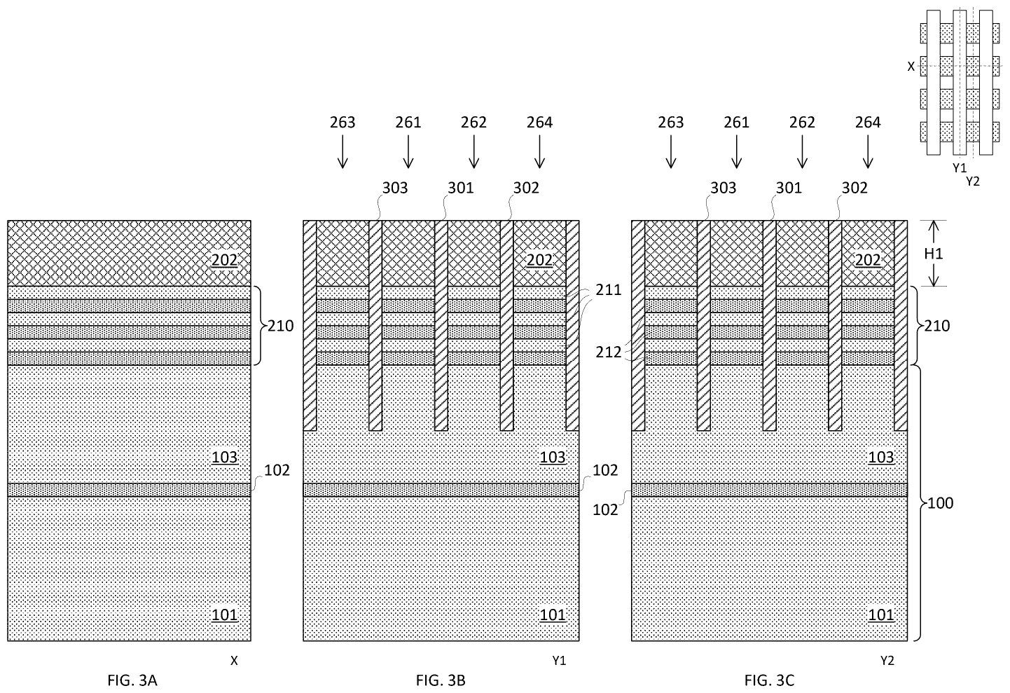

FIGS. 3A, 3B, and 3C are demonstrative illustrations of different cross-sectional views of a semiconductor structure in a step of manufacturing thereof according to one embodiment of present invention. More particularly, following the step illustrated in FIGS. 2A, 2B, and 2C, embodiments of present invention provide filling the one or more trench openings such as the first, the second, and the third trench opening 251, 252, and 253 with a dielectric material, such as SiO₂, SiN, SiOC, SiC, SiBCN, SiOCN, AIOx, and/or AlNx, etc. to form one or more dielectric bars such as, for example, a first, a second, and a third dielectric bar 301, 302, and 303. Filling the dielectric material into the one or more trench openings may be made through a deposition process such as, for example, a chemical vapor deposition (CVD) process, a physical vapor deposition (PVD) process, or an atomic layer deposition (ALD) process. Following the deposition, a chemical-mechanical-polishing (CMP) process may be applied to remove any excessive dielectric material from a top surface of the hard mask 202. The first, the second, and the third dielectric bar 301, 302, and 303 so formed may start within the Si layer 103 and extend through the one or more stacks of nanosheets 210 to reach a top surface of the hard mask 202. In other words, a portion of the first, the second, and the third dielectric bar 301, 302, and 303 may be made to be above a top surface of the one or more stacks of nanosheets 210.

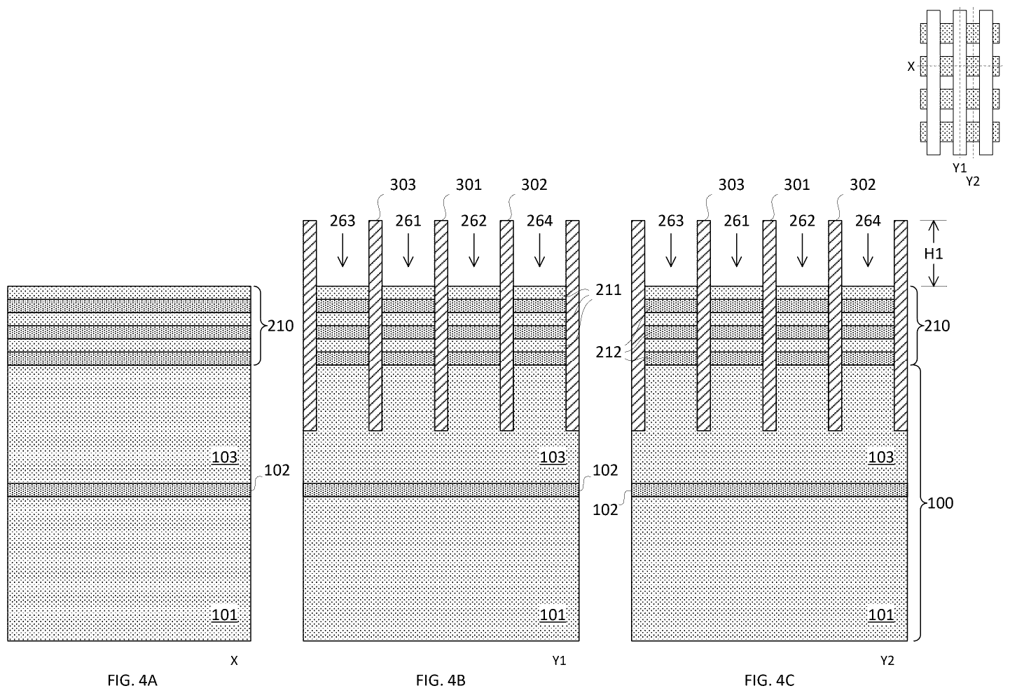

FIGS. 4A, 4B, and 4C are demonstrative illustrations of different cross-sectional views of a semiconductor structure in a step of manufacturing thereof according to one embodiment of present invention. More particularly, following the step illustrated in FIGS. 3A, 3B, and 3C, embodiments of present invention provide lifting the hard mask 202 above the one or more stacks of nanosheets 210, for example through an ash process, thereby causing portions of the one or more dielectric bars exposed. The exposed portions of the dielectric bars, such as the first, the second, and the third dielectric bar 301, 302, and 303, may have a height H1 above the top surfaces of the one or more stacks of nanosheets 210. In the meantime, embodiments of present invention provide forming the first dielectric bar 301 directly adjacent to, and between the first stack of nanosheets 261 and the second stack of nanosheets 262; forming the second dielectric bar 302 directly adjacent to, and between the second stack of nanosheets 262 and the fourth stack of nanosheets 264; and forming the third dielectric bar 303 directly adjacent to, and between the third stack of nanosheets 263 and the first stack of nanosheets 261.

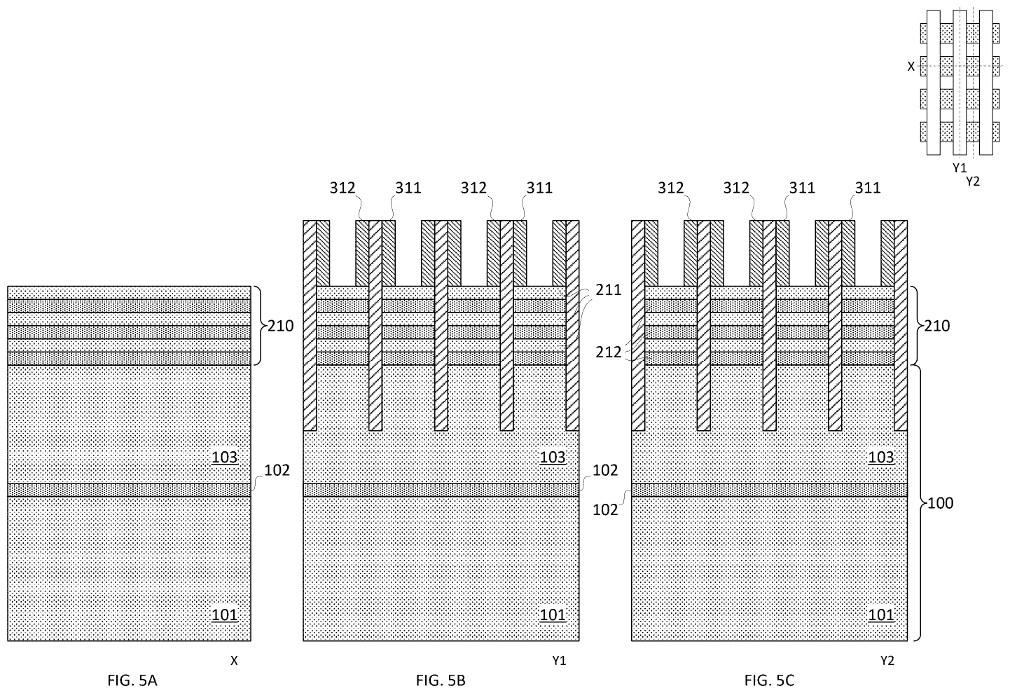

FIGS. 5A, 5B, and 5C are demonstrative illustrations of different cross-sectional views of a semiconductor structure in a step of manufacturing thereof according to one embodiment of present invention. More particularly, following the step illustrated in FIGS. 4A, 4B, and 4C, embodiments of present invention provide forming sidewall spacers at the left sidewalls and the right sidewalls of the portions of the one or more dielectric bars above the one or more stacks of nanosheets 210. For example, a first set of sidewall spacers 311 may be formed at the right sidewalls of the first, the second, and the third dielectric bar 301, 302, and 303 and a second set of sidewall spacers 312 may be formed at the left sidewalls of the first, the second, and the third dielectric bar 301, 302, and 303. The left sidewalls of the dielectric bars may be parallel to the right sidewalls of the dielectric bars to their left. For example, the left sidewall of the first dielectric bar 301 may be parallel to the right sidewall of the third dielectric bar 303. In other words, the right sidewalls of the dielectric bars may be parallel to the left sidewalls of the dielectric bars to their right. For example, the right sidewall of the first dielectric bar 301 may be parallel to the left sidewall of the second dielectric bar 302. The sidewall spacers 311 and 312 may be formed to have a thickness that is at least 6 nm, and preferably between 8 nm and 20 nm. The first set of sidewall spacers 311 may cover a first portion, for example a left portion, of the one or more stacks of nanosheets 210.

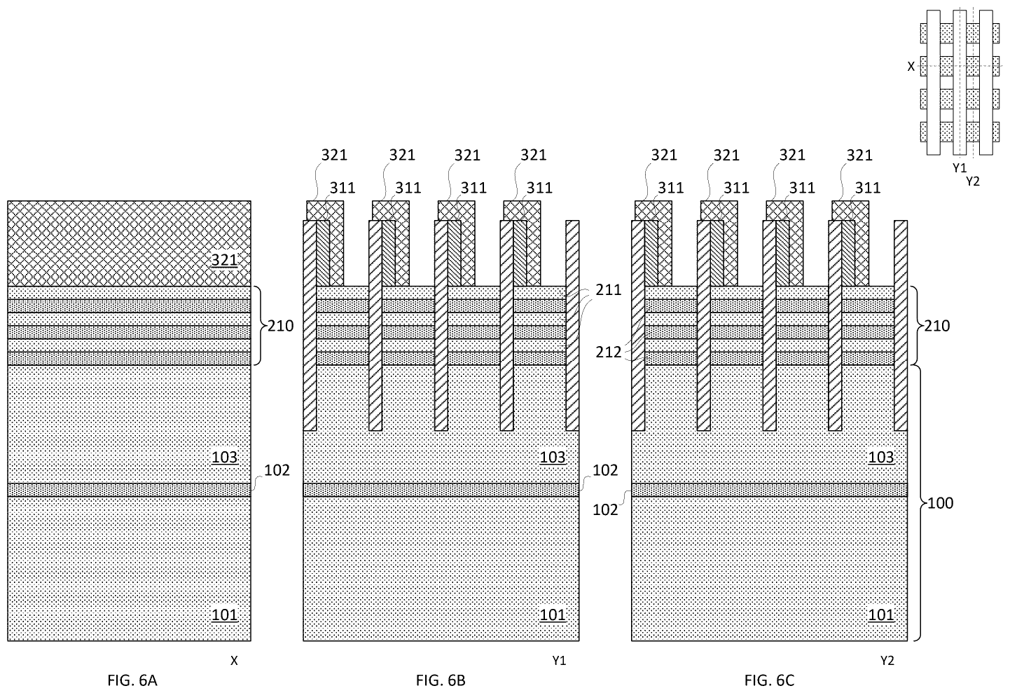

FIGS. 6A, 6B, and 6C are demonstrative illustrations of different cross-sectional views of a semiconductor structure in a step of manufacturing thereof according to one embodiment of present invention. More particularly, following the step illustrated in FIGS. 5A, 5B, and 5C, embodiments of present invention provide covering one set of sidewall spacers such as the first set of sidewall spacers 311. The first set of sidewall spacers 311 are at the right sidewalls of the one or more dielectric bars and are covered by a mask 321 such as an organic planarization layer (OPL). The non-covered therefore exposed second set of sidewall spacers 312 may be selectively removed through a selective etching process from the left sidewalls of the one or more dielectric bars. However, embodiments of present invention are not limited in this aspect and in one embodiment, the first set of sidewall spacers 311 at the right sidewalls of the one or more dielectric bars may be removed leaving the second set of sidewall spacers 312 at the left sidewalls of the one or more dielectric bars remaining and covered by a mask.

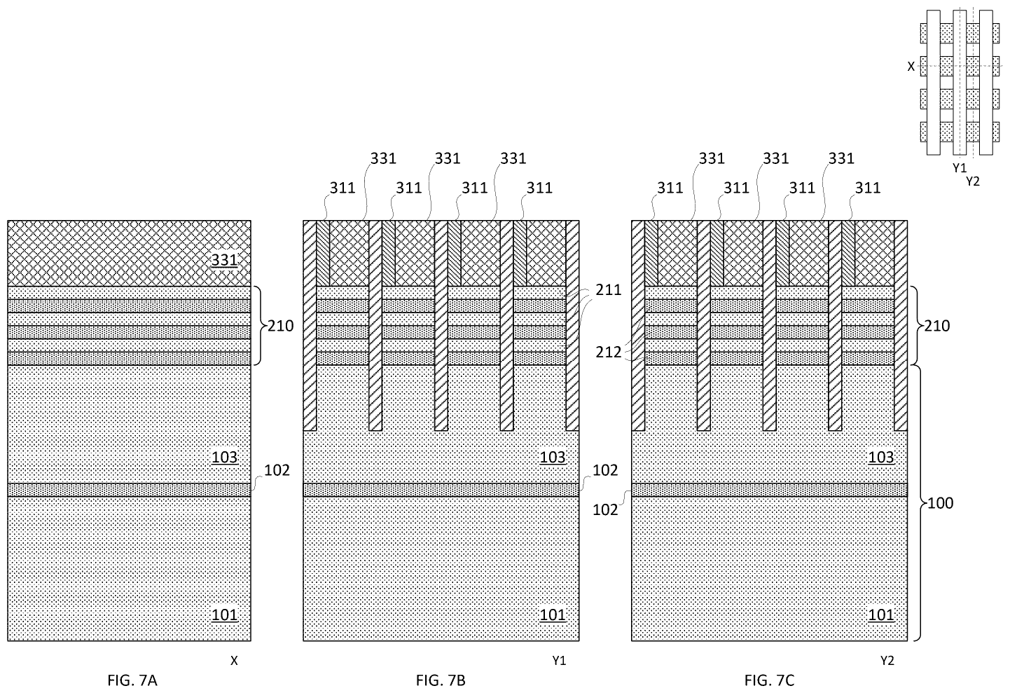

FIGS. 7A, 7B, and 7C are demonstrative illustrations of different cross-sectional views of a semiconductor structure in a step of manufacturing thereof according to one embodiment of present invention. More particularly, following the step illustrated in FIGS. 6A, 6B, and 6C, embodiments of present invention provide covering a second portion of the one or more stacks of nanosheets 210 that are not covered by the first set of sidewall spacers 311 with a mask layer 331 such as OPL or other suitable mask material, after optionally removing the mask 321. After forming the mask layer 331 to cover the exposed portions of the one or more stacks of nanosheets 210, an OPL etch back process may be applied to recess the mask layer 331, thereby exposing a top surface of the first set of sidewall spacers 311.

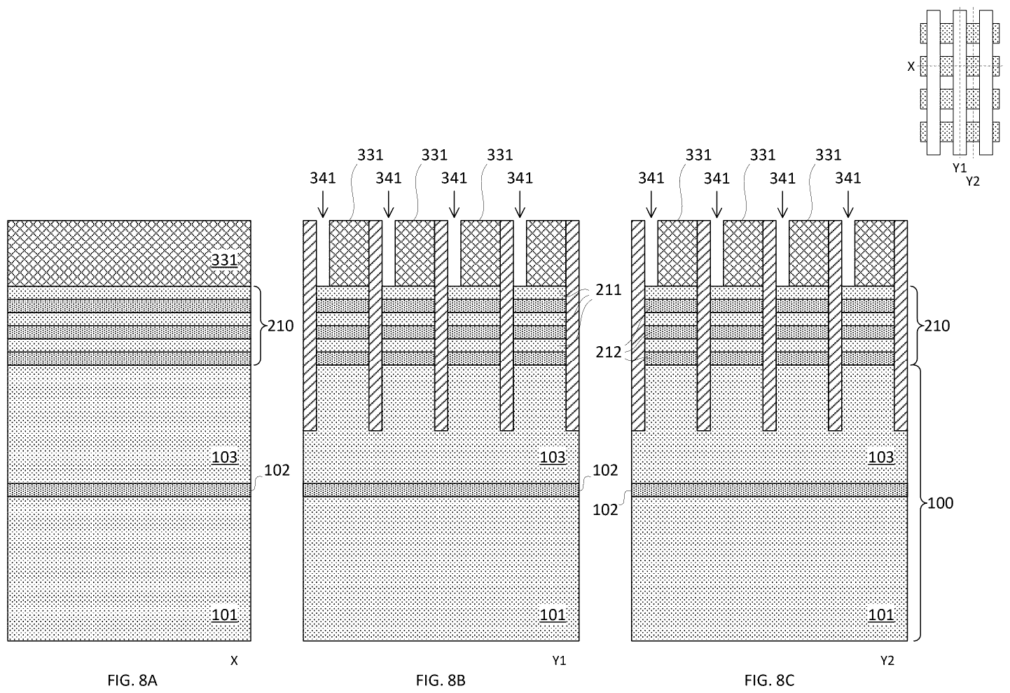

FIGS. 8A, 8B, and 8C are demonstrative illustrations of different cross-sectional views of a semiconductor structure in a step of manufacturing thereof according to one embodiment of present invention. More particularly, following the step illustrated in FIGS. 7A, 7B, and 7C, embodiments of present invention provide removing the first set of sidewall spacers 311 that are directly adjacent to the right sidewalls of the one or more dielectric bars such as the first, the second, and the third dielectric bar 301, 302, and 303. The removal of the first set of sidewall spacers 311 may be made through, for example, a selective etching process and may create a set of opening 341 adjacent to the right sidewalls of one or more dielectric bars such as the first, the second, and the third dielectric bars 301, 302, and 303. The set of openings 341 may expose the first portion of the one or more stacks of nanosheets 210.

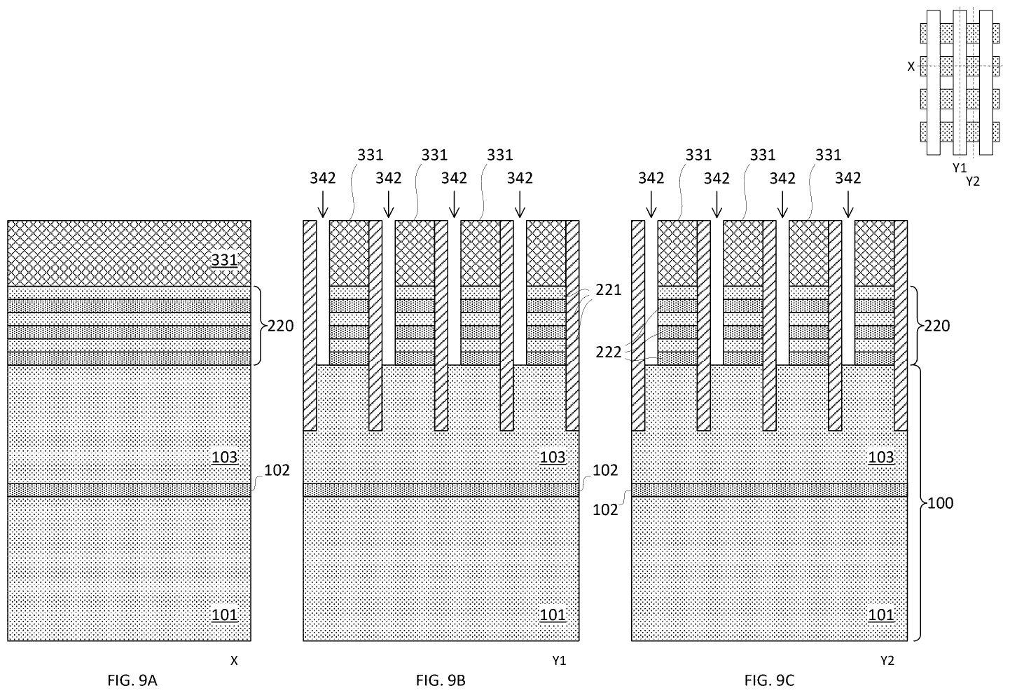

FIGS. 9A, 9B, and 9C are demonstrative illustrations of different cross-sectional views of a semiconductor structure in a step of manufacturing thereof according to one embodiment of present invention. More particularly, following the step illustrated in FIGS. 8A, 8B, and 8C, embodiments of present invention provide recessing the first portion of the one or more stacks of nanosheets 210 exposed by the set of openings 341 through, for example, a reactive-ion-etching (RIE) process. The RIE process may extend the set of openings 341 into a set of openings 342 until the underneath Si layer 103 is exposed.

The RIE process may also transform the one or more stacks of nanosheets 210, that is the second portion of the one or more stacks of nanosheets 210, into one or more raw sets of nanosheets 220. Each of the one or more raw sets of nanosheets 220 may include a raw set of Si nanosheets 221 separated by and/or alternating with a raw set of sacrificial sheets 222. The one or more raw sets of nanosheets 220, in particular the raw set of Si nanosheets 221, may be directly adjacent to the left sidewalls of the one or more dielectric bars such as the first, the second, and the third dielectric bar 301, 302, and 303. In the meantime, the raw set of Si nanosheets 221 may be separated from the right sidewalls of the first, the second, and the third dielectric bar 301, 302, and 303 by the set of openings 342.

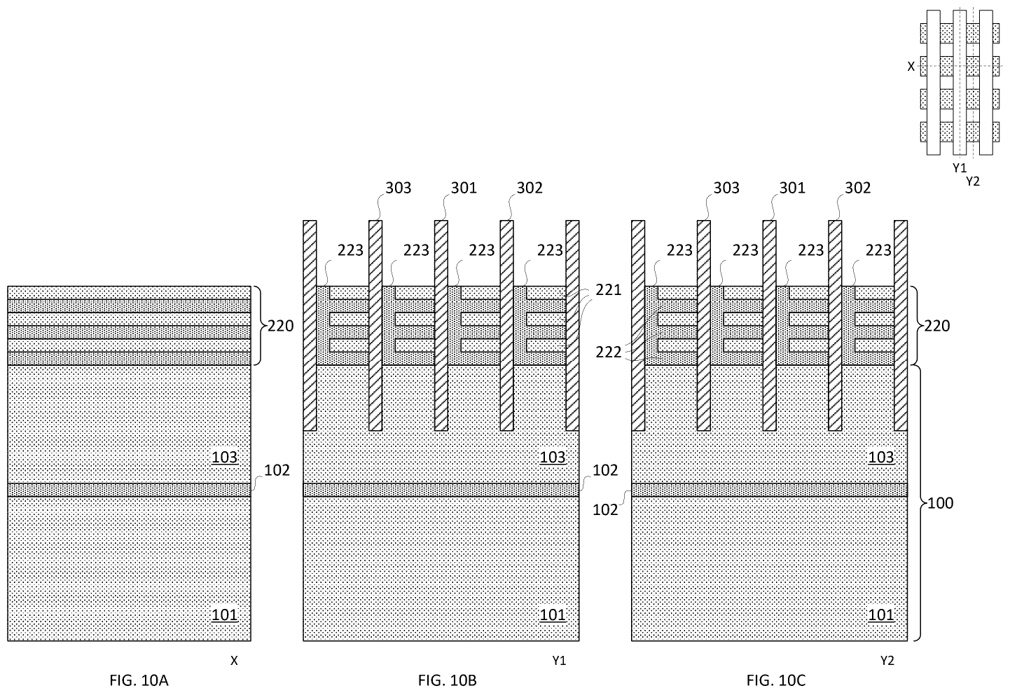

FIGS. 10A, 10B, and 10C are demonstrative illustrations of different cross-sectional views of a semiconductor structure in a step of manufacturing thereof according to one embodiment of present invention. More particularly, following the step illustrated in FIGS. 9A, 9B, and 9C, embodiments of present invention provide filling the set of openings 342, that is the openings between the one or more raw sets of nanosheets 220 and the right sidewalls of the one or more dielectric bars, with a sacrificial material. The sacrificial material may form one or more sacrificial fillers 223 and may be, for example, amorphous SiGe with a Ge content level similar to that of the raw set of sacrificial sheets 222. The raw set of sacrificial sheets 222, together with the sacrificial fillers 223, may be selectively removed later relative to the raw set of Si nanosheets 221. The mask layer 331 may be removed, either before or after forming the sacrificial fillers 223, to expose the one or more raw sets of nanosheets 220.

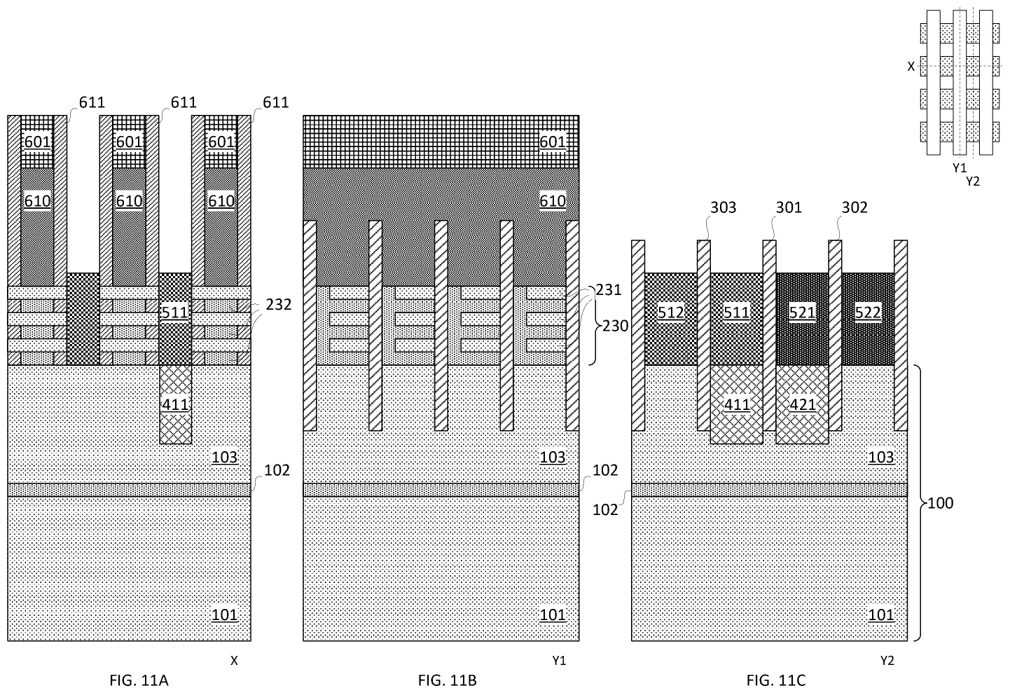

FIGS. 11A, 11B, and 11C are demonstrative illustrations of different cross-sectional views of a semiconductor structure in a step of manufacturing thereof according to one embodiment of present invention. More particularly, following the step illustrated in FIGS. 10A, 10B, and 10C, embodiments of present invention provide forming a set of dummy gates 610 through a lithographic patterning process using a dummy gate hard mask 601; and forming sidewall spacers 611 next to sidewalls of the set of dummy gates 610.

Using the set of dummy gates 610 as a mask, embodiments of present invention provide recessing the one or more raw sets of nanosheets 220 to create openings between the set of dummy gates 610, thereby transforming or truncating each of the one or more raw sets of nanosheets 220 into one or more sets of nanosheets 230 underneath each of the set of dummy gates 610. In other words, the one or more raw sets of nanosheets 220 may be patterned into a plurality of one or more sets of nanosheets 230. Each of the set of nanosheets 230 may include a set of Si nanosheets 231 and a set of sacrificial sheets 232, and the set of Si nanosheets 231 may be separated by or alternating with the set of sacrificial sheets 232.

Embodiments of present invention provide further recessing the Si layer 103 exposed by the recessing of the one or more raw sets of nanosheets 220 to create openings in the Si layer 103 between the set of dummy gates 610. The recessing may, to certain extent, remove a portion of the one or more dielectric bars in the region between and not covered by the set of dummy gates 610. Subsequently, embodiments of present invention provide filling the openings with a sacrificial material such as, for example, epitaxial SiGe or dielectric material, to form one or more placeholders (PHs) such as a first PH 411 between the third dielectric bar 303 and the first dielectric bar 301, and a second PH 421 between the first dielectric bar 301 and the second dielectric bar 302. for forming backside contacts later in the process. The PHs such as the first PH 411 and the second PH 421 may be used for forming backside contacts as being described below in more details.

After forming the PHs, inner spacers may be formed at the ends of the set of sacrificial sheets 232. Source/drain (S/D) regions may be formed between the set of dummy gates 610 and from the sidewalls of the one or more sets of nanosheets 230, particularly from the sidewalls of the set of Si nanosheets 231 while the set of sacrificial sheets 232 are covered by the inner spacers. For example, a n-type S/D region 511 may be epitaxially grown therefore formed above the first PH 411 and in the region between the third dielectric bar 303 and the first dielectric bar 301. Further for example, a p-type S/D region 521 may be formed above the second PH 421 and in the region between the first dielectric bar 301 and the second dielectric bar 302. The n-type S/D region 511 and the p-type S/D region 521 may be formed directly adjacent to the sidewalls of the one or more sets of nanosheets 230. Additional S/D regions such as a n-type S/D region 512 and a p-type S/D region 522 may be formed.

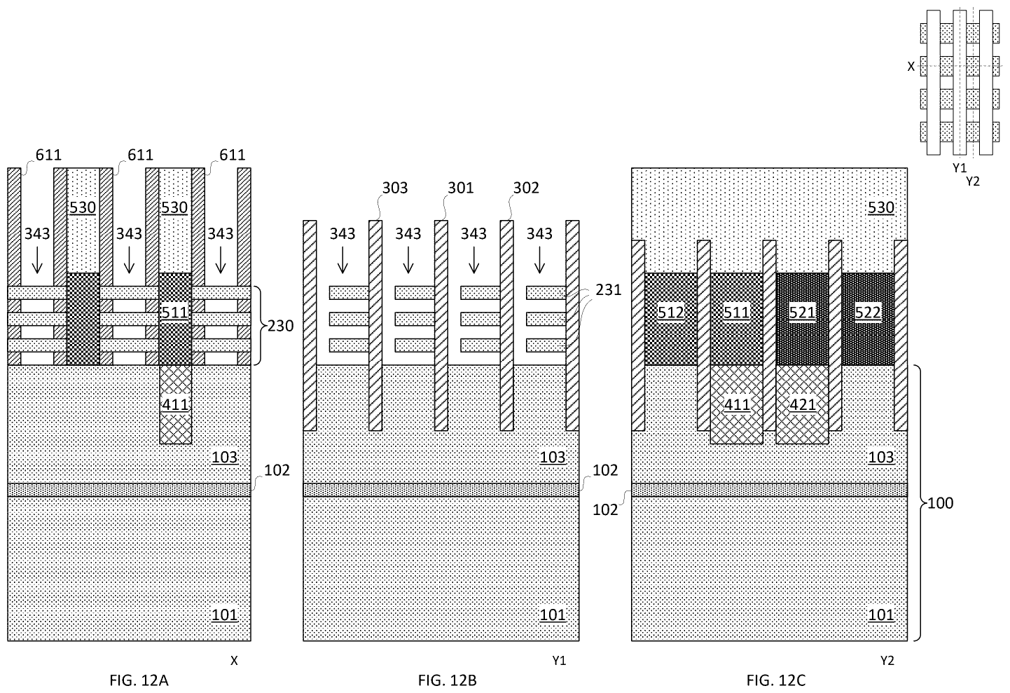

FIGS. 12A, 12B, and 12C are demonstrative illustrations of different cross-sectional views of a semiconductor structure in a step of manufacturing thereof according to one embodiment of present invention. More particularly, following the step illustrated in FIGS. 11A, 11B, and 11C, embodiments of present invention provide forming a dielectric layer 530 through, for example, a deposition process covering the S/D regions such as the n-type S/D regions 511 and 512 and the p-type S/D regions 521 and 522 between the set of dummy gates 610. Next, a CMP process may be applied to planarize the dielectric layer 530 and remove the hard mask 601 until the set of dummy gates 610 are exposed.

Embodiments of present invention further provide performing a replacement-metal-gate (RMG) process to form nanosheet transistors by first selectively removing material of the set of dummy gates 610, selectively removing the set of sacrificial sheets 232 between the set of Si nanosheets 231 of the one or more sets of nanosheets 230 to create spaces, and selectively removing the sacrificial fillers 223 that separate the one or more dielectric bars from the one or more sets of nanosheets 230 to create openings.

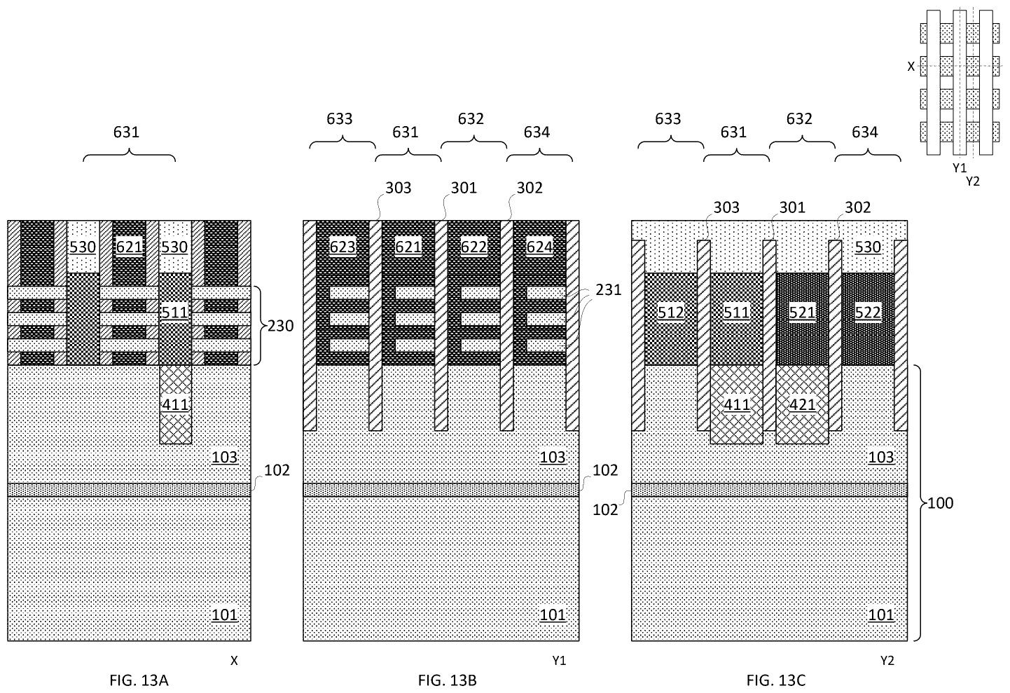

FIGS. 13A, 13B, and 13C are demonstrative illustrations of different cross-sectional views of a semiconductor structure in a step of manufacturing thereof according to one embodiment of present invention. More particularly, following the step illustrated in FIGS. 12A, 12B, and 12C, embodiments of present invention provide filling the spaces and openings created by the removal of the sacrificial sheets 232 and the sacrificial fillers 223 with a gate. The gate may surround the one or more sets of nanosheets and may include, for example, a layer of gate dielectric, one or more layers of work-function-metals (WFMs) on top of the gate dielectric, and one or more layers of conductive materials on top of the WFMs, thereby forming one or more nanosheet transistors with one or more metal gates. For example, a first n-type nanosheet transistor 631 may be formed having a first metal gate 621 between the first dielectric bar 301 and the third dielectric bar 303; a first p-type nanosheet transistor 632 may be formed having a second metal gate 622 between the first dielectric bar 301 and the second dielectric bar 302; a second n-type nanosheet transistor 633 may be formed having a third metal gate 623 and to the left side of the third dielectric bar 303; and a second p-type nanosheet transistor 634 may be formed having a fourth metal gate 624 and to the right side of the second dielectric bar 302.

The first and the second n-type nanosheet transistor 631 and 633 and the first and the second p-type nanosheet transistor 632 and 634 may each be referred to as a forksheet transistor. A forksheet transistor may be considered as a type of gate-all-around (GAA) transistor with a forked gate structure. The set of Si nanosheets 231 of each of the forksheet transistors may be directly adjacent to, attached to, and/or in contact with only one side of the dielectric bars respectively, and preferably consistently. By having the forksheet transistors formed only at one side, such as a left side, of the dielectric bars, it removes the necessity for having WFM undercut suppression during a manufacturing process when a different type of forksheet transistor is formed next to the other side, such as a right side, of the dielectric bars. Moreover, because the forksheet transistors are more uniformly spaced with each of them being attached to, directly adjacent to, and/or otherwise in contact with one dielectric bar respectively and being consistently at one side thereof, backside power rails of reasonable size may be used to provide power supply to the forksheet transistors. This in-turn improves the flexibility of wiring scheme and reduces any chance of short between neighboring backside power rails due to, for example, tight spacing otherwise found in prior art.

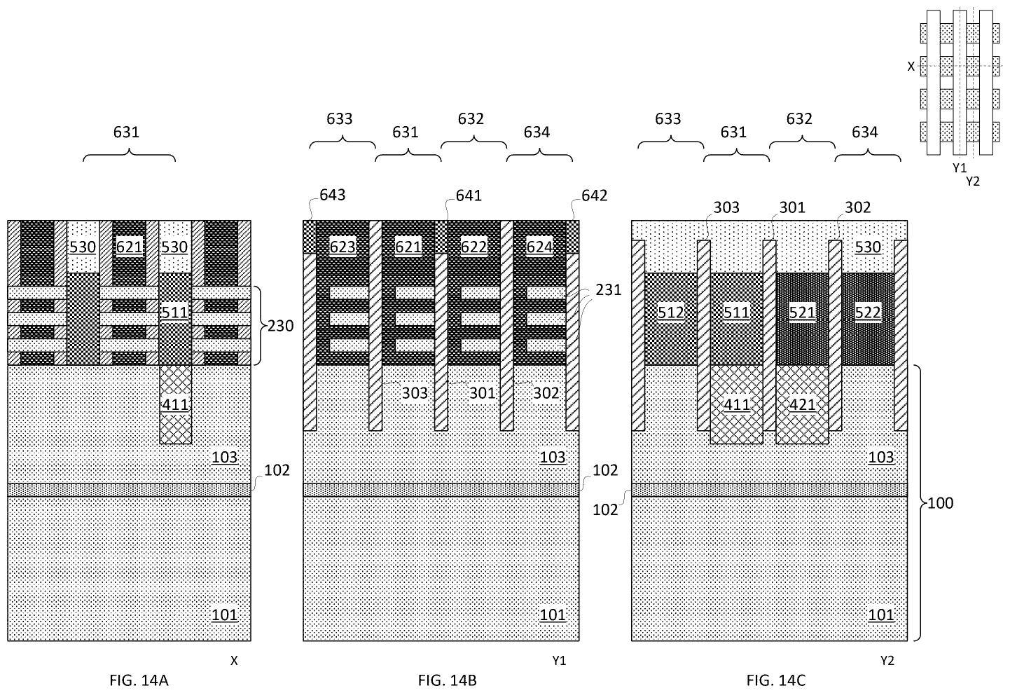

FIGS. 14A, 14B, and 14C are demonstrative illustrations of different cross-sectional views of a semiconductor structure in a step of manufacturing thereof according to one embodiment of present invention. More particularly, following the step illustrated in FIGS. 13A, 13B, and 13C, embodiments of present invention provide forming one or more metal connections that may connect gates of two neighboring nanosheet transistors, for example, between an n-type transistor and a p-type transistor across the dielectric bar therein-between. For example, the nanosheet transistor 631 is an n-type transistor and the nanosheet transistor 632 is a p-type transistor, a top portion of the first dielectric bar 301 between the two different types of transistors 631 and 632 may be recessed to create an opening. Next, a metal connection 641 may be formed in the opening by filling the opening with a conductive material and subsequently applying a CMP process to planarize the top surface of the metal connection 641. The resulting metal connection 641 may thus have a top surface that is coplanar with a top surface of some of the dielectric bars such as the second dielectric bar 302. In other words, the second dielectric bar 302 may have a top surface that is higher than the top surface of the first dielectric bar 301, which is covered by the metal connection 641. Additional metal connections such as metal connections 642 and 643 may be formed at top surfaces of some other dielectric bars. Example of metal connection 641, 642, 643 may be TiN, W, Ru, Al, etc.

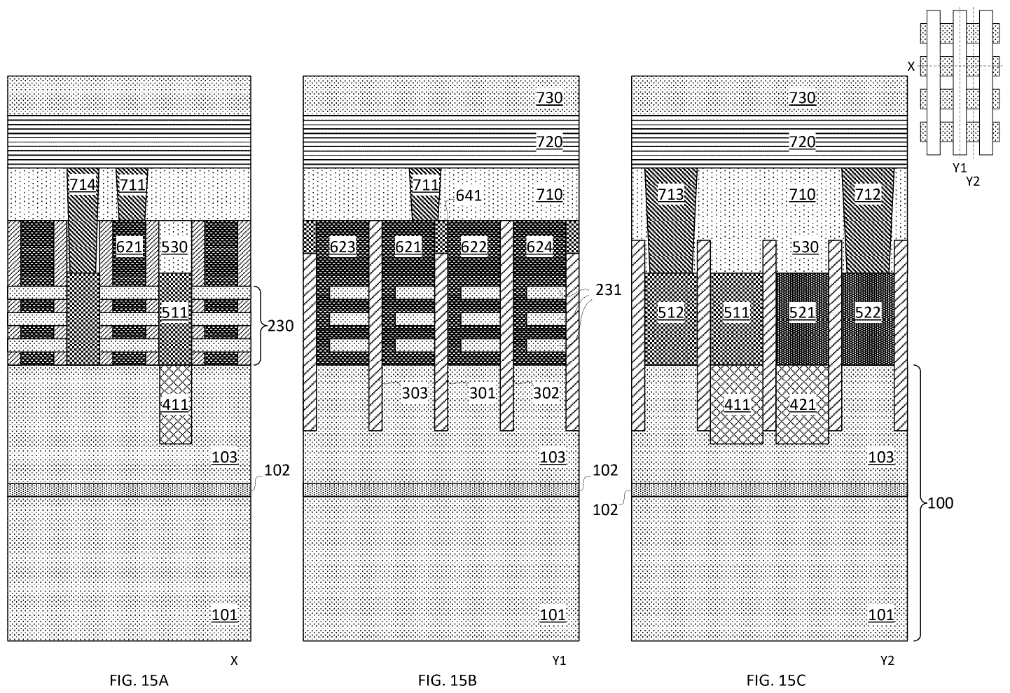

FIGS. 15A, 15B, and 15C are demonstrative illustrations of different cross-sectional views of a semiconductor structure in a step of manufacturing thereof according to one embodiment of present invention. More particularly, following the step illustrated in FIGS. 14A, 14B, and 14C, embodiments of present invention provide depositing additional dielectric layers such as, for example, a dielectric layer 710 on top of the dielectric layer 530 and covering the one or more metal gates such as metal gates 621, 622, 623, and 624. Embodiments of present invention further provide forming one or more mid-of-line (MOL) contacts in the dielectric layer 710 and/or 530 in conductive contact with gates and/or S/D regions of the underneath nanosheet transistors. For example, a MOL contact 711 may be formed in conductive contact with the metal gate 621 of the first n-type nanosheet transistor 631. MOL contacts 712 and 713 may be formed in conductive contact with S/D regions 522 and 512, respectively, of the second p-type nanosheet transistor 634 and the second n-type nanosheet transistor 633. Additional MOL contact such as MOL contact 714 may be formed as well.

Following the formation of various MOL contacts, embodiments of present invention provide forming a back-end-of-line (BEOL) structure 720 on top of and in contact with the one or more MOL contacts. The BEOL structure 720 may provide signal routing and/or power supply functions for the underneath one or more nanosheet transistors. Next, a carrier wafer 730 may be bonded onto the BEOL structure 720 such that the semiconductor structure 10 may be flipped upside down for further processing from the backside of the semiconductor substrate 100.

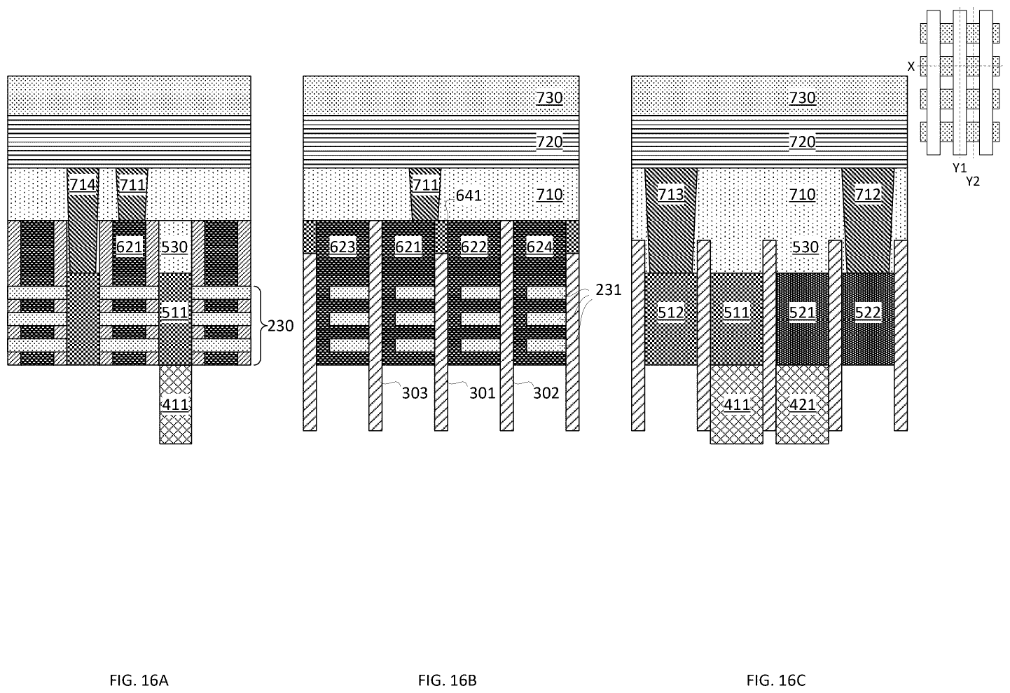

It is to be noted here that upside-up (instead of upside-down) drawings will continue to be used hereinafter for FIGS. 16A, 16B, and 16C to FIGS. 18A, 18B, and 18C, for the ease of illustration. However, description of the drawings may be provided in a manner that is consistent with processing from the backside of the semiconductor substrate 100.

FIGS. 16A, 16B, and 16C are demonstrative illustrations of different cross-sectional views of a semiconductor structure in a step of manufacturing thereof according to one embodiment of present invention. More particularly, following the step illustrated in FIGS. 15A, 15B, and 15C, embodiments of present invention provide removing the bulk Si substrate 101 through, for example, a CMP process, a grinding process, and/or in combination with other selective etching processes. The removal of the bulk Si substrate 101 may stop at the etch-stop layer 102. Embodiments of present invention may continue to remove the etch-stop layer 102 by changing the etchant that is selective to SiGe or material of the etch-stop layer 102. The selective removal of the etch-stop layer 102 may expose the underneath Si layer 103. The Si layer 103 may then be selectively removed as well, leaving the one or more PHs such as the first and the second PH 411 and 421 and lower portions of the one or more dielectric bars such as the first, the second, and the third dielectric bar 301, 302, and 303 exposed.

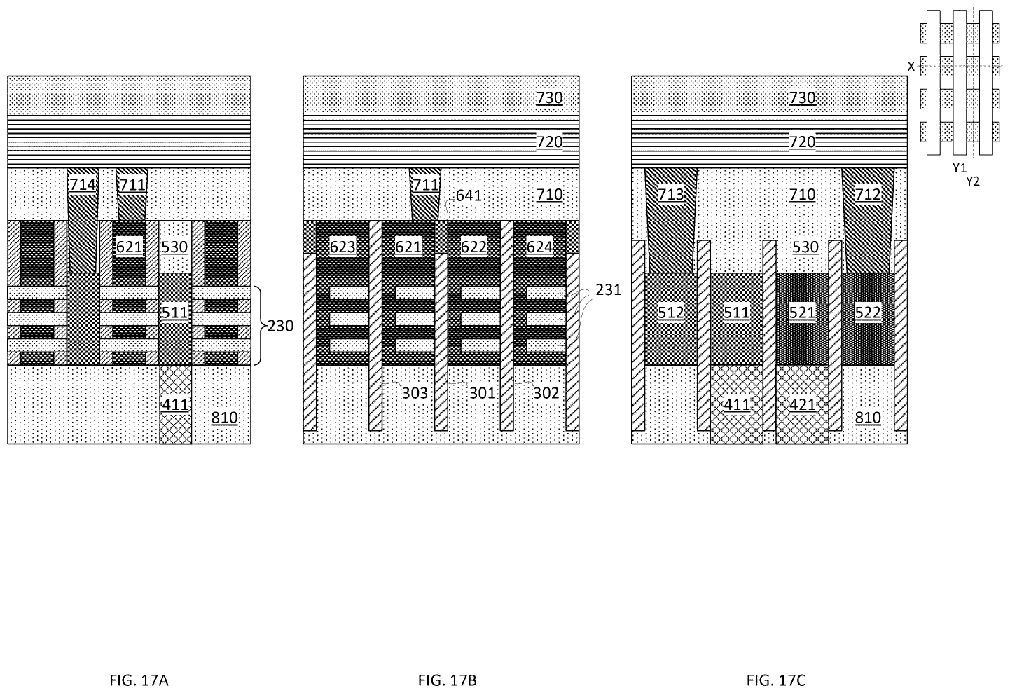

FIGS. 17A, 17B, and 17C are demonstrative illustrations of different cross-sectional views of a semiconductor structure in a step of manufacturing thereof according to one embodiment of present invention. More particularly, following the step illustrated in FIGS. 16A, 16B, and 16C, embodiments of present invention provide forming a backside interlevel dielectric (BILD) layer 810 covering the exposed PHs and dielectric bars. A CMP process may subsequently be applied to planarize the BILD layer 810 until the one or more PHs such as the first PH 411 and the second PH 421 are exposed.

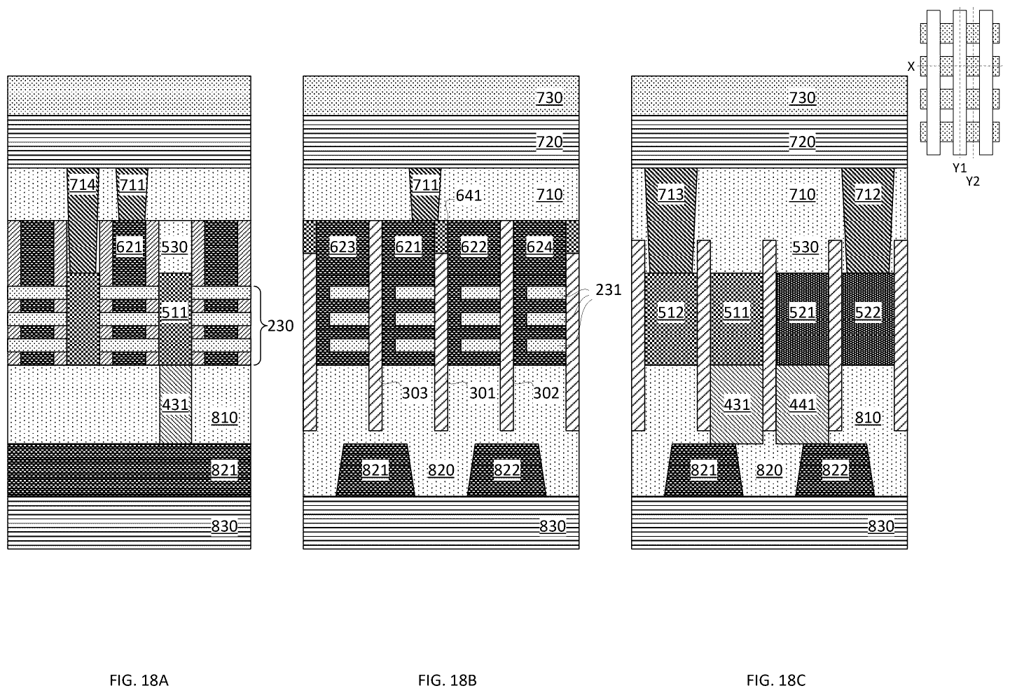

FIGS. 18A, 18B, and 18C are demonstrative illustrations of different cross-sectional views of a semiconductor structure in a step of manufacturing thereof according to one embodiment of present invention. More particularly, following the step illustrated in FIGS. 17A, 17B, and 17C, embodiments of present invention provide forming one or more backside contacts by replacing the sacrificial materials of the one or more PHs with conductive materials to form backside contacts. For example, the first PH 411 may be replaced with a first backside contact 431 and the second PH 421 may be replaced with a second backside contact 441. The first backside contact 431 may be in conductive contact with a bottom surface of the n-type S/D region 511 of the first n-type nanosheet transistor 631. Similarly, the second backside contact 441 may be in conductive contact with a bottom surface of the p-type S/D region 521 of the first p-type nanosheet transistor 632.

After forming the first and the second backside contacts 431 and 441, additional dielectric layer such as a backside interlevel dielectric (BILD) layer 820 may be deposited on top of the BILD layer 810 covering the backside contacts 431 and 441. In one embodiment, the BILD layer 820 may include a same material as the BILD layer 810. One or more backside power rails (BSPR's) such as a first BSPR 821 and a second BSPR 822 may be formed in the BILD layer 820. After forming the first and the second BSPR 821 and 822, additional structures such as a backside power distribution network (BSPDN) 830 may be formed on top of one or more BSPRs to be in conductive contact with, for example, the first and the second BSPR 821 and 822 for power distribution.

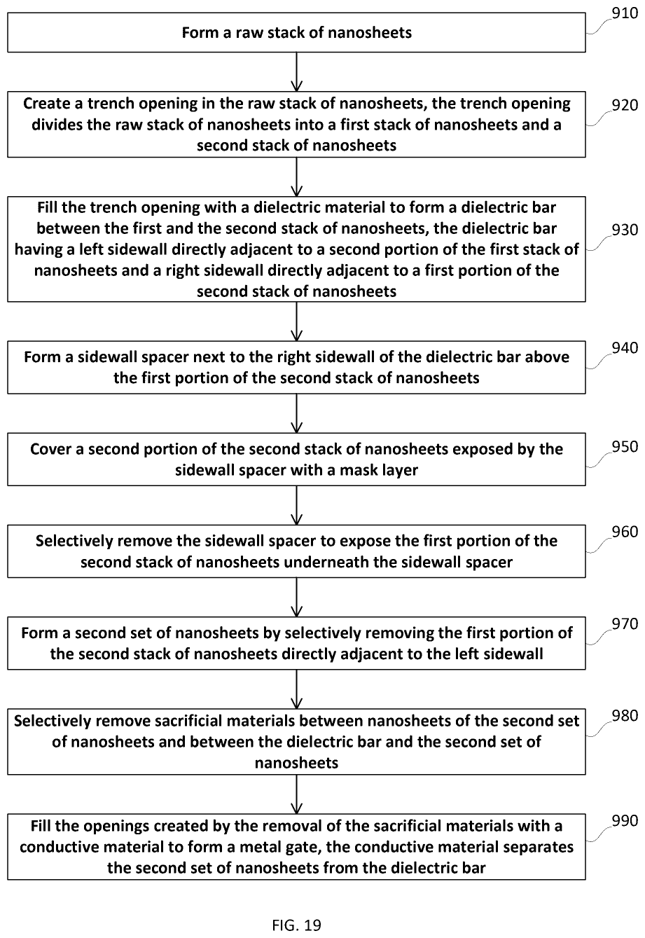

FIG. 19 is a demonstrative illustration of a flow-chart of a method of manufacturing a semiconductor structure according to embodiments of present invention. The method includes (910) forming a raw stack of nanosheets on top of a substrate; (920) creating a trench opening in the raw stack of nanosheets, the trench opening divides the raw stack of nanosheets into at least a first stack of nanosheets and a second stack of nanosheets; (930) filling the trench opening with a dielectric material to form a dielectric bar between the first and the second stack of nanosheets, the dielectric bar having a left sidewall directly adjacent to a second portion of the first stack of nanosheets and a right sidewall directly adjacent to a first portion of the second stack of nanosheets; (940) forming a sidewall spacer next to the right sidewall of the dielectric bar above the first portion of the second stack of nanosheets; (950) covering a second portion of the second stack of nanosheets that is exposed by the sidewall spacer with a mask layer; (960) selectively removing the sidewall spacer to expose the first portion of the second stack of nanosheets underneath the sidewall spacer; (970) forming a second set of nanosheets by at least selectively removing the first portion of the second stack of nanosheets that is directly adjacent to the left sidewall of the dielectric bar; (980) selectively remove the sacrificial materials between nanosheets of the second set of nanosheets and between the dielectric bar and the second set of nanosheets; and (990) filling the openings created by the removal of the sacrificial materials with a conductive material to form a metal gate, where the conductive material separates the second set of nanosheets from the dielectric bar.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a dielectric bar having a left sidewall and a right sidewall;
a first set of nanosheets having a first end and a second end, the second end of the first set of nanosheets directly adjacent to the left sidewall of the dielectric bar;
a first conductive layer directly adjacent to the left sidewall of the dielectric bar, the first conductive layer surrounding the first set of nanosheets and covering the first end of the first set of nanosheets; and
a second set of nanosheets and a second conductive layer, the second conductive layer separating the second set of nanosheets from the right sidewall of the dielectric bar.

2. The semiconductor structure of claim 1, wherein the dielectric bar is a first dielectric bar, further comprising a second dielectric bar,
wherein the second dielectric bar has a left sidewall parallel to the right sidewall of the first dielectric bar;
the second set of nanosheets has a first end and a second end with the second end of the second set of nanosheets being directly adjacent to the left sidewall of the second dielectric bar; and
the second conductive layer is directly adjacent to the left sidewall of the second dielectric bar; surrounds the second set of nanosheets; and covers the first end of the second set of nanosheets.

3. The semiconductor structure of claim 2, further comprising a first source/drain (S/D) region next to a first side of the first set of nanosheets, and a first backside contact in conductive contact with a bottom surface of the first S/D region.

4. The semiconductor structure of claim 3, further comprising a second S/D region next to a first side of the second set of nanosheets, and a second backside contact in conductive contact with a bottom surface of the second S/D region.

5. The semiconductor structure of claim 4, further comprising a metal connection on top of the first dielectric bar, the metal connection connects the first conductive layer with the second conductive layer.

6. The semiconductor structure of claim 5, wherein the first conductive layer is a gate metal of an n-type transistor, and the second conductive layer is a gate metal of a p-type transistor; the second dielectric bar has a height higher than a height of the first dielectric bar; and the second dielectric bar has a top surface that is coplanar with a top surface of the metal connection.

7. The semiconductor structure of claim 6, further comprising a third dielectric bar; a third set of nanosheets; and a third conductive layer,
wherein the third dielectric bar has a left sidewall and a right sidewall with the right sidewall of the third dielectric bar being parallel to the left sidewall of the first dielectric bar and wherein the first conductive layer separates the first set of nanosheets from the right sidewall of the third dielectric bar;
the third set of nanosheets has a second end directly adjacent to the left sidewall of the third dielectric bar; and
the third conductive layer is directly adjacent to the left sidewall of the third dielectric bar and surrounds the third set of nanosheets.

8. The semiconductor structure of claim 7, further comprising a first mid-of-line (MOL) contact in conductive contact with a top surface of the first conductive layer; a third S/D region next to a first side of the third set of nanosheets; and a second MOL contact in conductive contact with a top surface of the third S/D region.

9. The semiconductor structure of claim 8, further comprising a first backside power rail (BSPR) in contact with the first backside contact; a second BSPR in contact with the second backside contact; a backside power distribution network (BSPDN) in contact with the first and the second BSPRs; and a back-end-of-line (BEOL) in contact with the first and the second MOL contact.

10. A method of forming a semiconductor structure comprising:
forming a dielectric bar between a first stack of nanosheets and a second stack of nanosheets, the dielectric bar having a left sidewall directly adjacent to a second portion of the first stack of nanosheets and a right sidewall directly adjacent to a first portion of the second stack of nanosheets;
forming a first set of nanosheets by selectively removing a first portion of the first stack of nanosheets that is not directly adjacent to the left sidewall of the dielectric bar;
forming a second set of nanosheets by selectively removing the first portion of the second stack of nanosheets directly adjacent to the right sidewall of the dielectric bar;
forming a first conductive layer surrounding the first set of nanosheets and directly adjacent to the left sidewall of the dielectric bar; and
forming a second conductive layer surrounding the second set of nanosheets and directly adjacent to the right sidewall of the dielectric bar, the second conductive layer separates the second set of nanosheets from the dielectric bar.

11. The method of claim 10, wherein forming the dielectric bar between the first stack of nanosheets and the second stack of nanosheets comprises:
forming a raw stack of nanosheets;
creating a trench opening in the raw stack of nanosheets, the trench opening divides the raw stack of nanosheets into the first stack of nanosheets and the second stack of nanosheets; and
filling the trench opening with a dielectric material to form the dielectric bar.

12. The method of claim 10, further comprising, before forming the second set of nanosheets:
forming a sidewall spacer next to the right sidewall of the dielectric bar above the first portion of the second stack of nanosheets;
covering a second portion of the second stack of nanosheets with a mask layer;
selectively removing the sidewall spacer to expose the first portion of the second stack of nanosheets underneath the sidewall spacer.

13. The method of claim 10, wherein forming the second conductive layer comprises:
selectively removing a sacrificial material between the dielectric bar and the second set of nanosheets to create an opening;
selectively removing a set of sacrificial sheets between the second set of nanosheets to create spaces; and
filling the opening and the spaces with a conductive material in a replacement-metal-gate process to form the second conductive layer.

14. The method of claim 10, further comprising lowering a height of the dielectric bar to create an opening between the first conductive layer and the second conductive layer and filling the opening with a conductive material to form a metal connection.

15. The method of claim 10, further comprising forming a backside contact by replacing a placeholder underneath a source/drain (S/D) region, the S/D region being adjacent to a first side of the first set of nanosheets.

16. The method of claim 10, further comprising forming a mid-of-line (MOL) contact in contact with the first conductive layer surrounding the first set of nanosheets.

17. A semiconductor structure comprising:
a first and a second dielectric bar each having a left sidewall and a right sidewall;
a first set of nanosheets having a first end and a second end, the second end of the first set of nanosheets directly adjacent to the left sidewall of the first dielectric bar;
a first conductive layer surrounding the first set of nanosheets and directly adjacent to the left sidewall of the first dielectric bar;
a second set of nanosheets having a first end and a second end, the second end of the second set of nanosheets directly adjacent to the left sidewall of the second dielectric bar; and
a second conductive layer surrounding the second set of nanosheets; directly adjacent to the left sidewall of the second dielectric bar; and separating the second set of nanosheets from the right sidewall of the first dielectric bar.

18. The semiconductor structure of claim 17, further comprising a first source/drain (S/D) region next to a first side of the first set of nanosheets, and a first backside contact in conductive contact with a bottom surface of the first S/D region.

19. The semiconductor structure of claim 18, further comprising a metal connection on top of the first dielectric bar, the metal connection connects the first conductive layer with the second conductive layer.

20. The semiconductor structure of claim 19, wherein the first conductive layer is a gate metal of an n-type transistor, and the second conductive layer is a gate metal of a p-type transistor; the second dielectric bar has a height higher than a height of the first dielectric bar; and the second dielectric bar has a top surface that is coplanar with a top surface of the metal connection.
